(19) United States
(12) Patent Application Publication
(10) Pub. No.: US 2026/0123456 A1
(43) Pub. Date: Apr. 30, 2026

(54) ELECTRONIC DEVICE WITH LEAD INSULATION

(71) Applicant: Texas Instruments Incorporated, Dallas, TX (US)

(72) Inventors: Meng-Yu Ho, Taipei City (TW); Bob Lee, New Taipei City (TW); Hung-Yu Chou, New Taipei City (TW)

(21) Appl. No.: 18/925,148

(22) Filed: Oct. 24, 2024

(51) Int. Cl. H01L 23/495; H01L 21/48; H01L 23/00; H01L 23/31; H01L 23/498

(52) U.S. Cl. CPC H10W 70/458; H10W 70/048; H10W 70/429; H10W 74/111; H10W 70/60; H10W 72/884; H10W 90/736; H10W 90/756

(57) ABSTRACT

An electronic device includes a lead with a first portion that extends outward from a package structure and is coated with a dielectric film that extends to the side of the package structure, and an uncoated second portion that extends from the first portion to an end of the lead. A method includes forming a package structure to enclose an interior portion of a lead structure and coating an exterior first portion of the lead structure with a dielectric film that extends to a side of the package structure and leaving an exterior second portion of the lead structure uncoated.

### BACKGROUND

The working voltage of a packaged electronic device can be expressed in terms of creepage and clearance distances, often dependent upon package dimensions such as the package width and specified in various standards. Operating voltages between leads on opposite sides of a device can create an electric field across the isolator. Electrical breakdown of the package or the air below or alongside the package can increase the risk of electrical failure or arcing. Minimum creepage and clearance distances are defined by the IEC standards bodies as guidance intended to prevent air arcing during operation, such as IEC60664-1. Devices can be designed to accommodate higher working voltage applications, such as by using wider packages, but this reduces power density, increases the device cost and requires manufacturing tooling investment.

### SUMMARY

In one aspect, an electronic device includes a package structure and a lead that includes a first portion that extends outward from a side of the package structure and is coated with a dielectric film that extends to the side of the package structure, and an uncoated second portion that extends from the first portion to an end of the lead.

In another aspect, a system includes a circuit board having a conductive feature and an electronic device. The electronic device includes a package structure and a lead that includes a first portion that extends outward from a side of the package structure and is coated with a dielectric film that extends to the side of the package structure, and an uncoated second portion that extends from the first portion to an end of the lead, the uncoated second portion coupled to the conductive feature of the circuit board.

In a further aspect, a method of fabricating an electronic device includes forming a package structure to enclose an interior portion of a lead structure and coating an exterior first portion of the lead structure with a dielectric film that extends to a side of the package structure and leaving an exterior second portion of the lead structure uncoated.

### BRIEF DESCRIPTION OF THE DRAWINGS

FIG. 1 is a partial sectional side elevation view of a semiconductor device with leads partially coated with a dielectric layer taken along line 1-1 of FIG. 1A.

FIG. 1A is a top perspective view of the semiconductor device of FIG. 1.

FIG. 2 is a flow diagram of a method of fabricating a semiconductor device.

FIGS. 3-10 are partial sectional side elevation views of the semiconductor device of FIGS. 1 and 1A undergoing fabrication processing according to an implementation of the method of FIG. 2.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. In the following discussion and in the claims, the terms “including”, “includes”, “having”, “has”, “with”, or variants thereof are intended to be inclusive in a manner similar to the term “comprising”, and thus should be interpreted to mean “including, but not limited to”.

Unless otherwise stated, “about,” “approximately,” or “substantially” preceding a value means+/−10 percent of the stated value. One or more operational characteristics of various circuits, systems and/or components are hereinafter described in the context of functions which in some cases result from configuration and/or interconnection of various structures when circuitry is powered and operating. Described examples include doped regions of various semiconductor structures which may be characterized as p-doped and/or n-doped regions or portions and include regions that have majority carrier dopants of a particular type, such as n-type dopants or p-type dopants, and such regions or portions should be interpreted as having the conductivity type as n-type or p-type, respectively. One or more structures, features, aspects, components, etc., may be referred to herein as first, second, third, etc., such as first and second terminals, first, second, and third, wells, etc., for case of description in connection with a particular drawing, where such are not to be construed as limiting with respect to the claims. Various disclosed structures and methods of the present disclosure may be beneficially applied to manufacturing a semiconductor device such as an integrated circuit. While such examples may be expected to provide various improvements, no particular result is a requirement of the present disclosure unless explicitly recited in a particular claim.

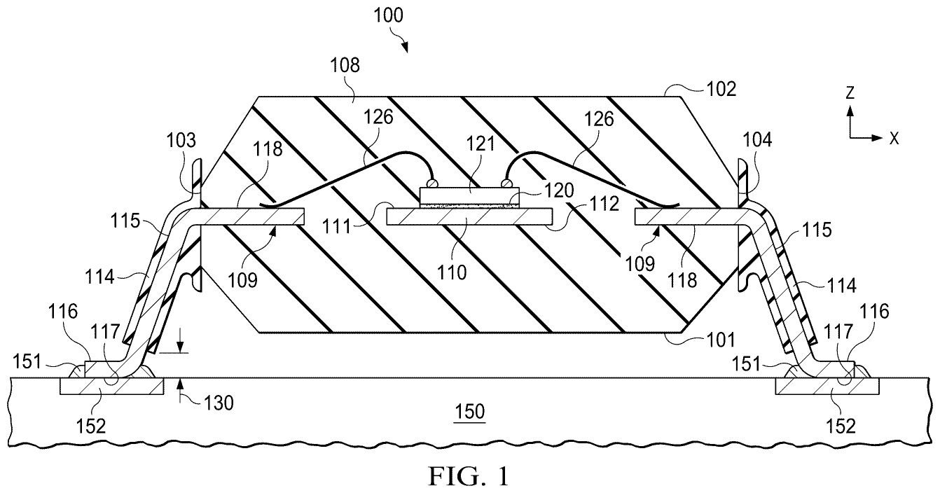

FIGS. 1 and 1A show an example electronic device 100, which may also be referred to as a semiconductor device or an integrated circuit (IC) with leads 109 having portions coated with a dielectric film 114. In the illustrated example, the package structure 108 encloses the die attach pad 110 along with the semiconductor die 121, any other included passive components (not shown) and the bond wires 126. The electronic device 100 in one example is an integrated circuit and can include one or more circuits formed by various components of the semiconductor die 121 and any other included dies and/or passive components (not shown).

The dielectric coating increases the creepage and clearance distances of the electronic device 100 by increasing the distance between uncoated conductive surfaces of leads 109 on opposite sides of the electronic device 100. This facilitates better voltage isolation and increased working voltage ratings without increasing the device dimensions. FIG. 1 shows a section view of the semiconductor device 100 taken along line 1-1 of FIG. 1A and FIG. 1A shows a top perspective view of the semiconductor device 100.

The electronic device 100 is illustrated in an example three-dimensional space with a first direction X, an orthogonal (e.g., perpendicular) second direction Y, and a third direction Z that is orthogonal (e.g., perpendicular) to the respective first and second directions X and Y. The electronic device 100 has a bottom or first side 101 and an opposite top or second side 102 that are spaced apart from one another along the third direction Z. Laterally opposite third and fourth sides 103 and 104 of the electronic device 100 are spaced apart from one another along the first direction X, and opposite fifth and sixth ends or sides 105 and 106 (FIG. 1A) are spaced apart from one another along the second direction Y.

The sides 101-106 in one example are defined by a molded package structure 108 that encloses circuitry and components of the electronic device 100. In another example, the package structure 108 can be a ceramic structure or other suitable material. The leads 109 are or include a conductive metal, such as aluminum or copper or alloys thereof. The illustrated leads 109 are gullwing leads that extend outward from a respective one of the third and fourth sides 103 and 104 and downward to form a landing portion with a planar bottom side 117 (FIG. 1) that is below the bottom or first side 101 of the electronic device 100. In other examples, different forms and types of leads or conductive terminals can be used, and other implementations can include leads on one or more sides 103-106.

As shown in FIG. 1, the electronic device 100 includes a die attach pad 110 with a top or first side 111 and an opposite bottom or second side 112. A semiconductor die 121 is attached to the first side 111 of the die attach pad 110 using a conductive or nonconductive die attach film 120. The semiconductor die 121 has top side conductive metal features, such as bond pads (not numerically designated), which are coupled by bond wires 126 in FIG. 1 to respective leads 109 of the electronic device 100. The electronic device 100 can include bond wires 126 (not shown) that provide electrical interconnections of various components and structures (e.g., semiconductor dies, leads 109, etc.). In other examples, discrete electronic components (e.g., surface mount resistors, capacitors, etc.) can be electrically interconnected in circuitry of the electronic device 100, for example, and can be mounted to other support structures and can be interconnected by bond wires and/or solder connections (not shown).

The example electronic device has gullwing leads 109 along the opposite third and fourth sides 103 and 104 of the package structure 108. The example leads 109 have interior portions that are enclosed by the package structure 108 as well as external portions that extend outward from a corresponding side 103, 104 (e.g., along the first direction X), and extend downward to bottom or end portions that are configured to be soldered to a host circuit board 150 by solder connections 151 as shown in FIG. 1. Alternatively, the electronic device 100 can be installed in a socket (not shown) with the leads 109 engaged with corresponding conductive features of the socket to form electrical connections to a host system. FIG. 1 shows an example system implementation, in which the system circuit board 150 has traces or pads or other conductive features 152, and the conductive terminals or leads 109 of the electronic device 100 are soldered to respective conductive features 151 of the circuit board 150.

The individual leads 109 have respective coated and uncoated exterior portions 115 and 116 that are outside the package structure 108, as well as an interior portion 118 (FIG. 1) that is enclosed by the package structure 108. A coated exterior first portion 115 of the individual leads 109 extends outward from a respective one of the third and fourth sides 103 and 104 the package structure 108. The first portion 115 is coated with the dielectric film 114 that extends to the respective side 103, 104 of the package structure 108. In one example, the dielectric film 114 extends along a generally planar vertical portion of the respective sides 103 and 104 of the package structure 108. In the illustrated example, the dielectric film 114 includes upwardly extending portions that extend on, and in some implementations beyond the vertical portion of the sides 103 and 104 as well as downwardly extending portions that extend downward along the third direction Z on, and in some implementations beyond the vertical portion of the respective sides 103 and 104 as shown in FIGS. 1 and 1A. In the illustrated example, moreover, the upwardly and downwardly extended portions of the dielectric film 114 have curved or arcuate outer portions, and generally planar in her portions resulting from masked deposition processing used to form the dielectric film 114. As best shown in FIG. 1, moreover, the downwardly extended portions of the dielectric film 114 have an arcuate inwardly extending concave profile between the respective package side 103, 104 and the first portions 115 of the respective leads 109. In another example, the concave shape of the downwardly extended portions of the dielectric film 114 can have deeper or shallower profiles. In a further example, the downwardly extended portions of the dielectric film 114 can completely fill the lateral space (e.g., along the first direction X) along the inner sides of the leads 109 and may not have a concave profile. The upwardly and downwardly extended portions of the dielectric film 114 can advantageously increase the creepage and/or clearance distance of the electronic device 100.

An uncoated second portion 116 of each lead 109 in one example extends from the first portion 115 to the end of the lead 109. The uncoated second portion 116 can advantageously facilitate solder connection and/or interconnection with a circuit board socket (not shown) to electrically couple the leads 109 of the electronic device 100 to the circuit board 150. The dielectric film 114 in one example covers all sides of the first portion 115 of the individual leads 109, including the top, bottom and lateral sides of the first portion 115 of the individual leads 109. In one example, the uncoated second portion 116 includes an uncoated planar side 117 configured for soldering to a circuit board 150. In one example, the dielectric film 114 is or includes polyimide. In one example, the dielectric film 114 is or includes metal oxide, such as hafnium oxide or any suitable stoichiometry. The dielectric film 114 in one example is spaced apart from a plane of the uncoated planar side 117 by a non-zero spacing distance 130. The uncoated second portion 116 extends from the first portion 115 to an end of the lead 109 and the uncoated second portion 116 coupled to the conductive feature 152 of the circuit board 150 by solder 151 as shown in FIG. 1.

The electronic device 100 advantageously provides a small size package that occupies minimal host circuit board space while improving the creepage and/or clearance distances for voltage isolation between leads 109 on opposite sides (e.g., 103 and 104) of the device 100. The selective coding of the first portions 115 of the leads 109 provides a low-cost solution to enable high-voltage operation along with high power and circuit density.

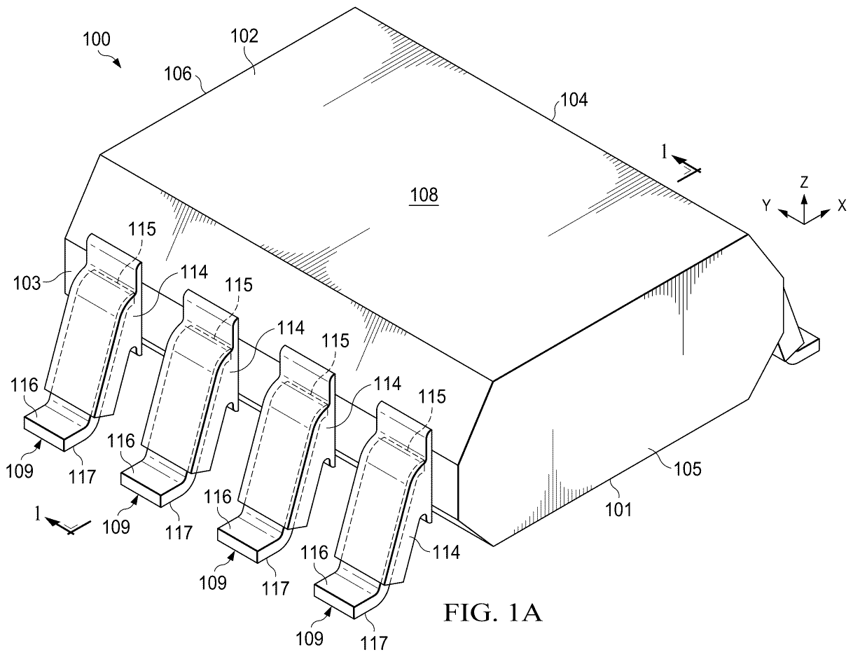

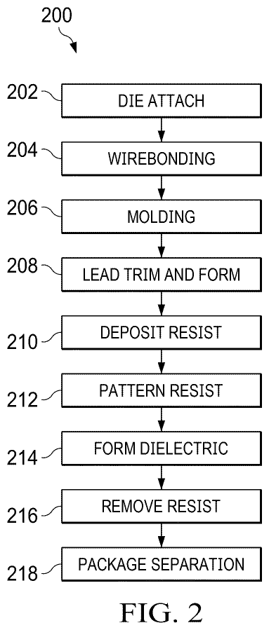

Referring also to FIGS. 2-10, FIG. 2 shows a method 200 of fabricating a semiconductor device, and FIGS. 3-10 show the semiconductor device 100 of FIGS. 1 and 1A undergoing fabrication processing according to an implementation of the method 200. The method 200 begins with die attach processing at 202 in FIG. 2 to attach one or more semiconductor dies and any included passive surface mount components. FIG. 3 shows one example, in which a die attach process 300 is performed using a starting lead frame panel array 302, which can include multiple rows and columns of unit areas that individually correspond to a respective prospective packaged electronic device, one of which is shown in FIG. 3. The illustrated unit area of the lead frame panel array 302 includes prospective lead portions 109 on opposite lateral sides of a die attach pad feature 110 that is spaced apart along the first direction X from the prospective lead portions 109.

The die attach process 300 attaches the semiconductor die 121 to the top side of the die attach pad 110 using a die attach film adhesive 120. In one example, an adhesive formation process is performed that forms the adhesive (e.g., die attach film) 120 along select portions of the top side of the die attach pad 110 in each unit area of the substrate array panel 302. Any suitable adhesive formation process and die attach film or other adhesive 120 can be used, which can be conductive or nonconductive. In one example the adhesive formation process can be a dispensing, silk screening, printing or other suitable process that forms the adhesive 120 on to the first side 111 of the die attach pad 110. Attachment processing is then performed that attaches the appropriate semiconductor dies (e.g., an instance of the semiconductor die 121 in each unit area) and any included passive surface mount components (not shown) to the previously formed adhesive 120 along the first side 111 of the die attach pad 110 (e.g., and any other designated support structures) in each unit area of the lead frame panel array 302, for example, using automated pick and place equipment (not shown). In one implementation, a post attachment adhesive curing process can be performed at 202 in FIG. 2. In one example, a thermal curing process is performed that cures the adhesive 120 in each unit area of the lead frame panel array 302. In other examples, a different curing process can be used (e.g., ultraviolet or UV curing, etc.) based on the type of die attach film or adhesive 120 used in a given implementation.

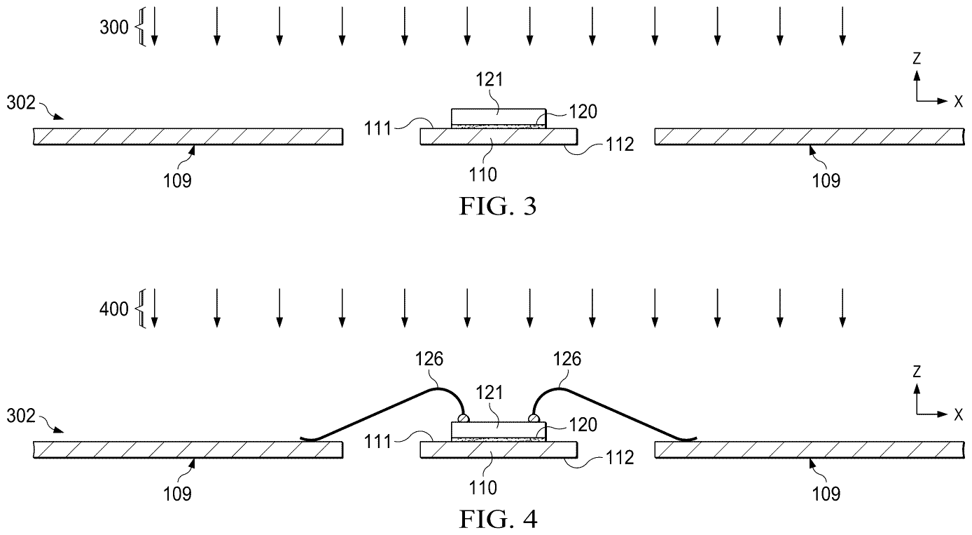

The method 200 in the illustrated example continues at 204 with wire bonding or other suitable electrical interconnection processing. FIG. 4 shows one example, in which a wire bonding process 400 is performed that forms the bond wires 126 between corresponding conductive terminals (e.g., bond pads) along the front sides of the attached semiconductor dies 121 and corresponding connection points (e.g., prospective leads 109) in each unit area of the lead frame panel array 302. The wire bonding processing at 204 in FIG. 2 may also be used to form other bond wire connections (not shown) in each unit area of the lead frame panel array 302. In another implementation, select portions of the prospective lead structures 109 can be coated with the dielectric material 114 prior to wire bonding at 204, for example, leaving the portions to which a bond wire 126 is to be attached, uncoated.

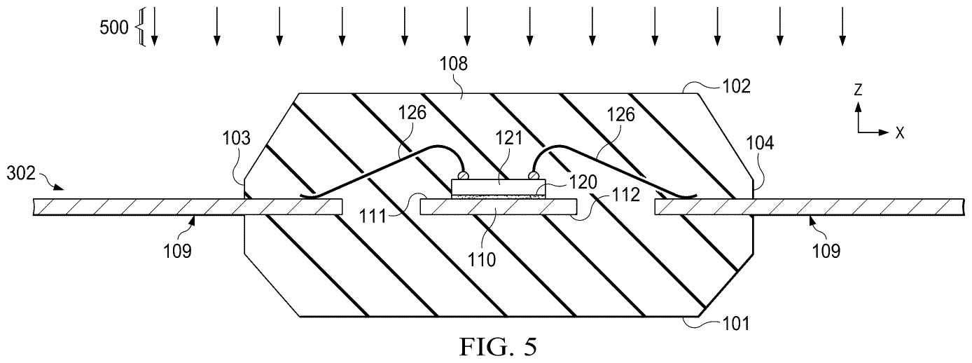

The method 200 continues at 206 in FIG. 2 with package formation to form the package structure 108. FIG. 5 shows one example, in which a molding process 500 is performed that forms the package structure 108 including the sides 101-106 as described above in connection with FIGS. 1 and 1A. In one example, the lead frame panel array structure allows for concurrent molding of multiple unit areas, where the molding process 500 in one example can form a single or shared molded package structure 108 along an entire column of unit areas, which are subsequently separated such as by saw cutting or other separation processing (not shown). In another example, the molding process 500 uses a mold structure (not shown) having individual cavities for corresponding unit areas of the lead frame panel array configuration, and each of the individual cavities forms the corresponding ends or sides 105 and 106 of the individual molded package structures 108. In another implementation, select portions of the prospective lead structures 109 can be coated with the dielectric material (e.g., 114 in FIGS. 1 and 1A) prior to molding at 206.

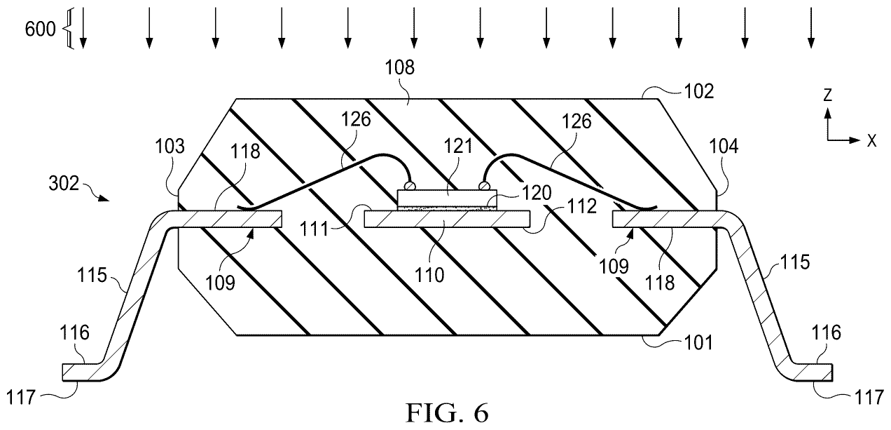

In the illustrated example at 208 in FIG. 2, the prospective lead portions 109 of the starting lead frame panel array 302 are trimmed and formed before selective coating with the dielectric material 114. In other implementations, designated portions of the prospective leads 109 can be coated with the dielectric material 114 after lead trimming and prior to lead forming. In the illustrated example, lead trimming and forming is performed at 208 prior to selective dielectric coating. FIG. 6 shows one example, in which a lead trim and form process 600 is performed that trims the prospective leads 109 between adjacent unit areas of the lead frame panel array structure 302. In this example, the process 600 includes lead forming using suitable tooling (not shown) that forms the desired bends and creates the illustrated gullwing leads 109 of each prospective semiconductor device 100 in each unit area of the lead frame panel array 302.

The method 200 continues in one example at 210-216 in FIG. 2 with selective coating of the prospective exterior first portion 115 of the trimmed and formed lead structures 109 in each unit area of the lead frame panel array 302. As discussed above, the selective dielectric coating can be performed at different points in the fabrication process 200. For example, the prospective first portions 115 of the individual prospective lead portions 109 of the lead frame panel array 302 can be selectively coated with the dielectric film 114 prior to die attach processing at 202. In another example, the selective dielectric coating can be applied to designated portions of the lead frame panel array 302 after die attach processing at 202 and prior to wire bonding or other electrical interconnection at 204. In a further example, the dielectric coating processing can be performed after wire bonding at 204 and prior to molding at 206 in FIG. 2. In yet another example, the designated portions of the lead frame panel array 302 can be selectively coated with the dielectric material 114 after molding processing at 206 and prior to lead trimming, with the lead forming at 208 being performed after the selective dielectric material coating.

Any of these processing sequences can be chosen for a given manufacturing process and device design, for example, to advantageously reduce cost and/or manufacturing complexity associated with the dielectric material coatings. Lead forming operations, such as punch die and other tooling that contacts the prospective lead portions 109 of the lead frame panel array 302 in some examples can be adjusted or tailored to accommodate the presence of the dielectric material 114 to mitigate or avoid damage to the dielectric material 114 or exposure of the previously coated conductive metal surfaces of the prospective first portions 115 of the prospective leads 109 by contact during lead trimming and/or lead forming at 208.

The illustrated example includes both trimming and forming the lead structures 109 at 208 before coating the exterior first portions 115 of the respective lead structures 109 at 210-216. This approach can advantageously avoid the possibility of lead trimming and forming equipment damaging the dielectric material coating 114 during manufacturing. Any suitable dielectric material formation processing can be used that coats the exterior first portion 115 of the individual lead structures 109 and leaves the exterior second portion 116 of the individual lead structures uncoated. In the illustrated implementation, moreover, the dielectric coating processing extends the dielectric film 114 extends to a respective one of the sides 103 or 104 of the package structure 108. The dielectric film 114 may extend onto portions of the molded package structure 108 along one or both of the sides 103, 104, although not a requirement of all possible implementations. Moreover, exposed conductive material (e.g., copper) of one or more of the leads 109 at or near the side 103, 104 of the package structure 108 are possible in various implementations, while the remainder of the coated parts of the first portions 115 of the leads 109 still beneficially serve to enhance or extend the creepage and/or clearance distances of the finished electronic device 100.

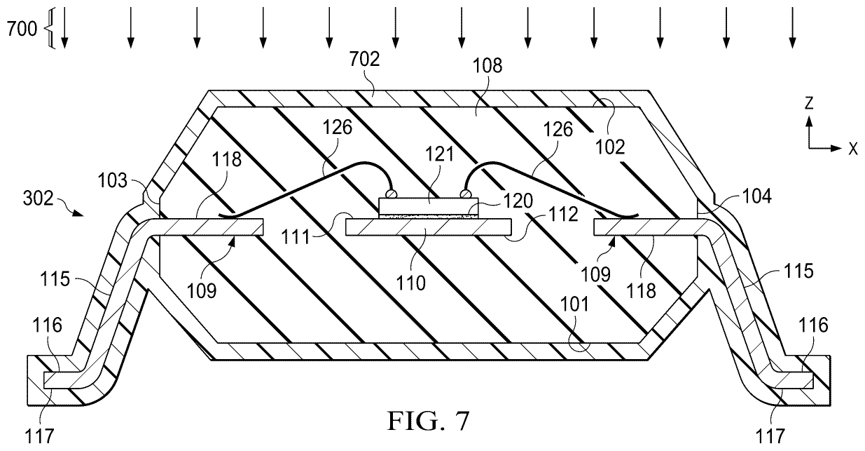

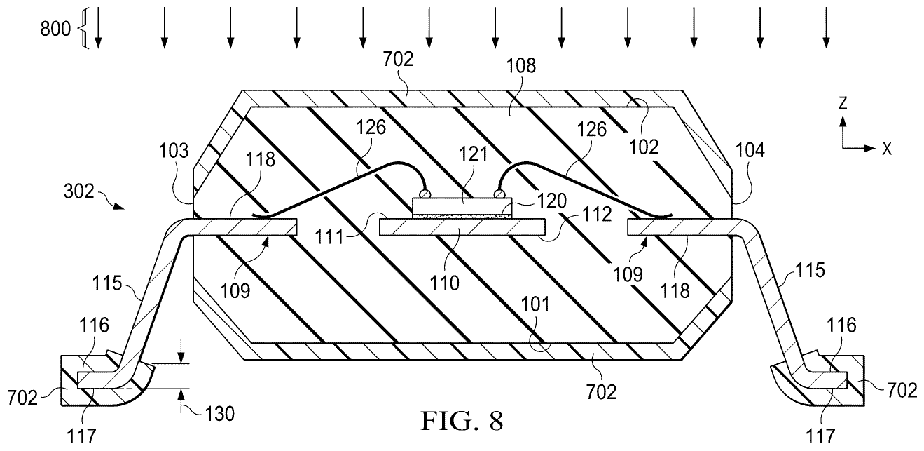

The example implementation of the method 200 includes forming a resist material layer at 210 and patterning the resist at 212 in FIG. 2 to form a patterned resist mask, an example of which is illustrated in FIGS. 7 and 8. At 210 in FIG. 2 in this example, a deposition process 700 is performed as shown in FIG. 7 that forms a resist material layer 702 that extends over and covers the top, bottom, and lateral side surfaces of the package structure 108 and the trimmed and formed leads 109 in each unit area of the lead frame panel array 302. Any suitable resist material 702 and thickness can be used. In one implementation, the resist material 702 is a negative photoresist, such as Polyimide, HD4100, etc., which can also be a dielectric layer precursor. One example implementation uses a PIMEL™ photo resist, which is a photosensitive PI material available from Asahi Kasei Corporation of Tokyo Japan, to provide a negative photoresist coating that is also dielectric layer precursor (e.g., a photo-definable polyimide precursor).

At 212 in FIG. 2, the example implementation includes patterning the resist material 702. FIG. 8 shows one example, in which a patterning process 800 is performed using a photomask and light source (not shown), that exposes the resist material 702 in the prospective uncoated second portions 116 of the leads 109 and the resist material 702 along the package structure 108 and does not expose the resist material 702 associated with the prospective first portions 115 of the individual trimmed and formed leads 109. In this example, the exposed part of the resist material 702 will be insoluble to a development solvent, and the unexposed part will be soluble to the development solvent. The patterning process 800 in this example includes applying a solvent to the exposed and unexposed portions of the resist material 702 to remove the soluble unexposed resist material 702 from the prospective first portions 115 of the leads 109 as shown in FIG. 8, leaving the patterned mask that covers the exterior second portion 116 of the lead structure and exposes the exterior first portion 115 of the lead structure 109.

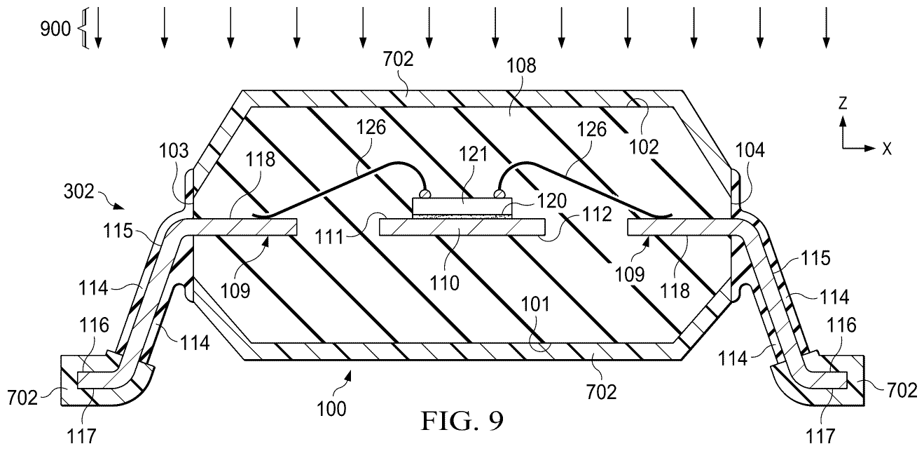

The method 200 continues at 214 in FIG. 2 with forming the dielectric material or film 114. FIG. 9 shows one example, in which a deposition process 900 is performed that forms the dielectric film 114 along the top, bottom, and lateral sides of the unmasked first portions 115 of the respective leads 109. Any suitable deposition process 900 and dielectric material 114 can be used. The deposition process 900 can form the deposited dielectric film 114 to any suitable thickness to provide a desired level of electrical insulation, with the beneficial increase in the creepage and/or clearance distance of the finished electronic device 100. In one example, the deposition process 900 deposits the dielectric film 114 as polyimide. In another example, the deposition process 900 deposits the dielectric film 114 as a metal oxide, such as hafnium dioxide (e.g., HfO₂) of any suitable stoichiometry to operate as a dielectric.

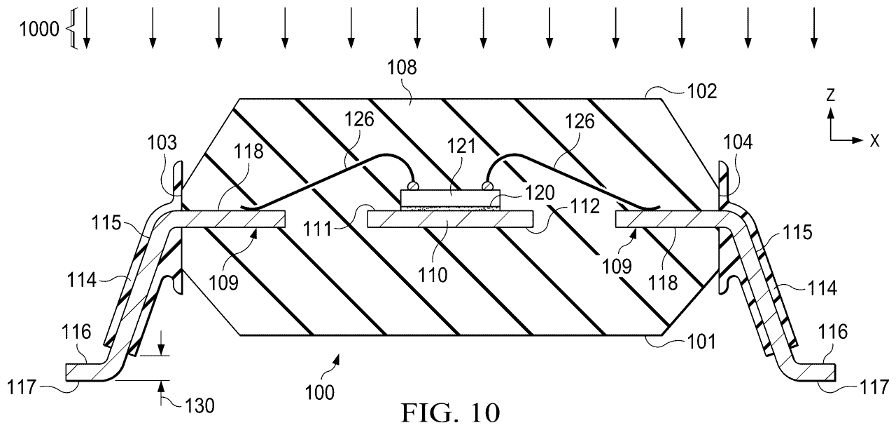

The method 200 in this example continues at 216 in FIG. 2 with removing the patterned mask. FIG. 10 shows one example, in which a resist stripping or other suitable resist material removal process 1000 is performed that removes the patterned mask 702 from the exterior second portions 116 of the individual lead structures 109. The process 1000 also removes the patterned resist mask material 702 from the molded package structure 108 as shown in FIG. 10.

The method 200 continues at 218 in FIG. 2 with electronic device separation or singulation from the starting substrate panel array structure 302. In one example, the package separation includes saw cutting separates individual packaged electronic devices 100 from jointly molded unit areas along columns of the lead frame panel array structure 302. Following package separation processing at 218, the separated packaged electronic devices 100 are depicted as shown in FIGS. 1 and 1A above. In other examples, different separation processes and tools can be used, such as laser cutting, chemical etching, etc. (not shown).

The described semiconductor device 100 and fabrication methods 200 can be advantageously employed to increase creepage and clearance distances of a given electronic device design by adding an insulating dielectric film on select portions of the leads 109 and any suitable point in a manufacturing process. This provides performance benefits without increasing device dimensions, with little or no cost impact on the manufacturing process besides the cost of additional dielectric film and provides the finished electronic device 100 with a planar lead surfaces of the second portions 116 that are suitable for soldering to a host circuit board (e.g., FIG. 1 above). In certain implementations of gullwing lead devices (e.g., electronic device 100 above), the selectively coated leads 109 can provide significant increases in creepage, for example, greater than 10%.

Modifications are possible in the described embodiments, and other embodiments are possible, within the scope of the claims.

The following is claimed:

1. An electronic device, comprising:
a package structure; and
a lead including a first portion that extends outward from a side of the package structure and is coated with a dielectric film that extends to the side of the package structure, and an uncoated second portion that extends from the first portion to an end of the lead.

2. The electronic device of claim 1, wherein the dielectric film includes polyimide.

3. The electronic device of claim 1, wherein the dielectric film includes metal oxide.

4. The electronic device of claim 1, wherein the uncoated second portion includes an uncoated planar side configured for soldering to a circuit board.

5. The electronic device of claim 4, wherein the dielectric film is spaced apart from a plane of the uncoated planar side by a non-zero spacing distance.

6. The electronic device of claim 1, wherein the dielectric film covers all sides of the first portion.

7. A system, comprising:
a circuit board having a conductive feature; and
an electronic device, including:
a package structure; and
a lead including a first portion that extends outward from a side of the package structure and is coated with a dielectric film that extends to the side of the package structure, and an uncoated second portion that extends from the first portion to an end of the lead, the uncoated second portion coupled to the conductive feature of the circuit board.

8. The system of claim 7, wherein the dielectric film includes polyimide.

9. The system of claim 7, wherein the dielectric film includes metal oxide.

10. The system of claim 7, wherein the uncoated second portion includes an uncoated planar side configured for soldering to a circuit board.

11. The system of claim 10, wherein the dielectric film is spaced apart from the circuit board by a non-zero spacing distance.

12. The system of claim 7, wherein the dielectric film covers all sides of the first portion.

13. A method of fabricating an electronic device, the method comprising:
forming a package structure to enclose an interior portion of a lead structure; and
coating an exterior first portion of the lead structure with a dielectric film that extends to a side of the package structure and leaving an exterior second portion of the lead structure uncoated.

14. The method of claim 13, further comprising trimming the lead structure to separate the lead structure from a lead frame before coating the exterior first portion of the lead structure.

15. The method of claim 14, further comprising forming the lead structure before coating the exterior first portion of the lead structure.

16. The method of claim 13, wherein coating the exterior first portion of the lead structure includes:
forming a patterned mask that covers the exterior second portion of the lead structure and exposes the exterior first portion of the lead structure;
depositing the dielectric film on the exposed exterior first portion of the lead structure; and
removing the patterned mask from the exterior second portion of the lead structure.

17. The method of claim 16, wherein depositing the dielectric film includes performing a spray deposition process (900) that covers all sides of the exposed exterior first portion with the dielectric film.

18. The method of claim 13, further comprising trimming the lead structure to separate the lead structure from a lead frame after coating the exterior first portion of the lead structure.

19. The method of claim 13, wherein the dielectric film includes polyimide.

20. The method of claim 13, wherein the dielectric film includes metal oxide.
